(19) United States
(12) Patent Application Publication
(10) Pub. No.: US 2024/0421202 A1
(43) Pub. Date: Dec. 19, 2024

(54) FEEDTHROUGH VIA BETWEEN ACTIVE REGIONS

(71) Applicant: Taiwan Semiconductor Manufacturing Company, Ltd., Hsin-Chu (TW)

(72) Inventors: Chia-Wei Chen, Hsinchu (TW); I-Wen Wu, Hsinchu City (TW); Chen-Ming Lee, Taoyuan County (TW); Ming-Cheng Syu, Hsinchu City (TW)

(21) Appl. No.: 18/335,525

(22) Filed: Jun. 15, 2023

(51) Int. Cl. H01L 29/417; H01L 27/088; H01L 29/06; H01L 29/423

(52) U.S. Cl. CPC H01L 29/41766; H01L 27/088; H01L 29/0673; H01L 29/42392

(57) ABSTRACT

One aspect of the present disclosure pertains to a semiconductor structure. The semiconductor structure includes first and second active regions extending lengthwise along a first direction and metal gate structures extending lengthwise along a second direction over channels of the first and second active regions. The semiconductor structure includes an insulating structure cutting through the metal gate structures. The insulating structure is disposed between the first and the second active regions along the second direction. The semiconductor structure includes source/drain (S/D) contacts over the insulating structure and over S/D features of the first and second active regions. The S/D contacts extend lengthwise along the second direction. And the semiconductor structure includes a feedthrough via contacting a bottom surface of the S/D contacts and penetrating through a portion of the insulating structure. The insulating structure surrounds the feedthrough via and isolates the feedthrough via from the metal gate structures.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

One advancement is in the use of feedthrough vias to connect signals from the frontside of the wafer to the backside of the wafer. This allows for flexibility in forming semiconductor features on both front and backsides of a semiconductor structure. In one example, the feedthrough vias may electrically connect frontside source/drain features to a backside power rail. However, forming feedthrough vias are often costly due to the space they take up. For example, the feedthrough vias are formed inside a feedthrough cell isolated from adjacent active regions. In these cases, the feedthrough vias are formed between inactive regions, which take up additional space in the circuit layout. This in turn increases the spacing between active regions, decreasing functional density. To integrate feedthrough vias more effectively and to save space, feedthrough vias may be formed directly between active regions without a dedicated nonactive feedthrough cell. However, this may cause risks in shorting the feedthrough vias to other active metal structures such as the metal gates.

Therefore, although existing methods of forming feedthrough vias have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a semiconductor structure having a feedthrough via surrounded by a cut-metal-gate structure, according to an embodiment of the present disclosure.

FIG. 2 illustrates a flow chart of a method to form a semiconductor structure having a feedthrough via surrounded by a cut-metal-gate structure, according to an embodiment of the present disclosure.

FIG. 3 illustrates a flow chart of a method to form a feedthrough via surrounded by a cut-metal-gate structure, according to an embodiment of the present disclosure.

FIGS. 4-12 (including any corresponding sub-figures A-D, which includes FIGS. 4A-4D, 5A-5D, 6A-6D, 7B-7D, 8B-8D, 9B-9D, 10B-10D, 10B-1, 10C-1, 10D-1, 11A, 11A-1, 11B-11D, 12B-12D, 13B-13D, and 14B-14D), illustrate the formation of a semiconductor structure at intermediate stages of fabrication and at different top and cross-sectional views, processed in accordance with the method of FIG. 2, according to an embodiment of the present disclosure. Note that some of these figures do not include sub-figures A, which shows a top view of the semiconductor structure.

FIGS. 13B-13D illustrate an embodiment semiconductor structure at the cross-sectional views cut along the lines B-B′, C-C′, and D-D′ in FIG. 11A.

FIGS. 14B-14D illustrate another embodiment semiconductor structure at the cross-sectional views cut along the lines A-A′, B-B′, and C-C′ in FIG. 11A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm.

The present disclosure relates to semiconductor structures having a feedthrough via formed directly between active regions. No additional dummy structures are formed between the feedthrough via and the active regions, thereby reducing the spacing between active regions. To ensure that the feedthrough via is properly isolated from the active metal gates, the feedthrough via is formed within and surrounded by a cut-metal-gate structure. The cut-metal-gate feature may cut through not only the active metal gates, but also an interlayer dielectric (ILD) layer and an isolation structure (or a portion thereof). By properly patterning and forming the cut-metal-gate structure, the feedthrough via is seamlessly integrated with the active regions. Since the feedthrough via is not formed in an isolated cell, the feedthrough via may directly contact active source/drain contacts. The source/drain contacts may be slot source/drain contacts that contact many source/drain features. This provides a direct vertical route for signals to travel from a backside of the semiconductor structure to the source/drain features. Note that the cut-metal-gate structure also isolates adjacent source/drain contacts.

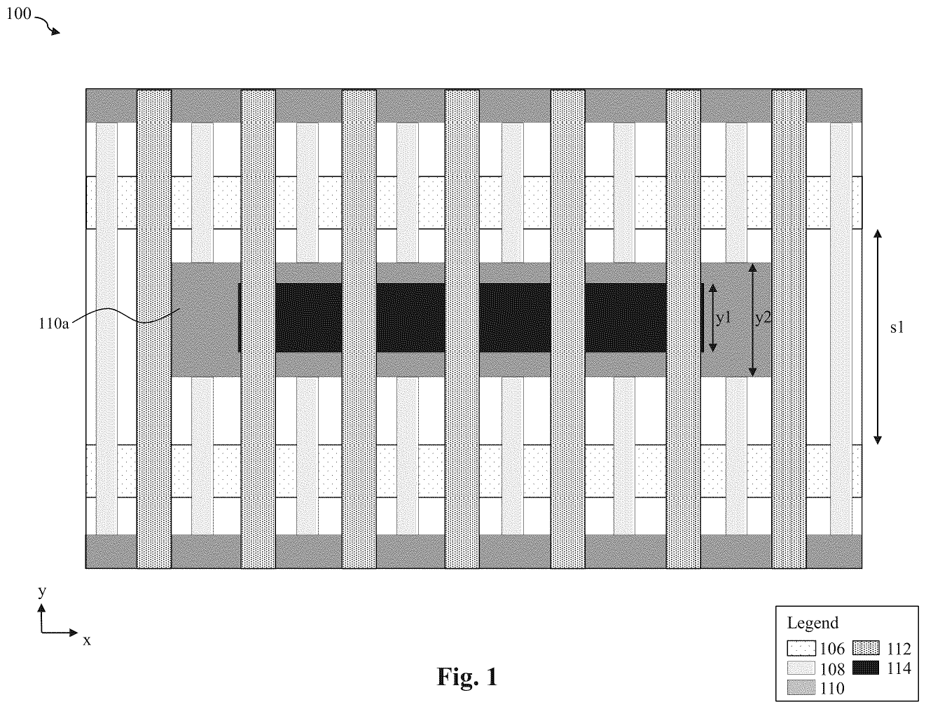

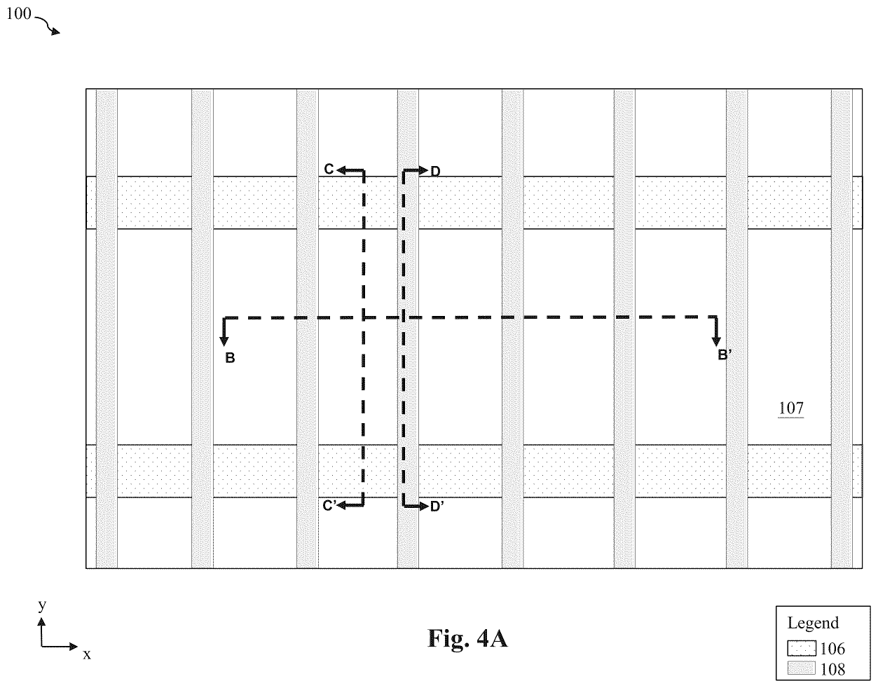

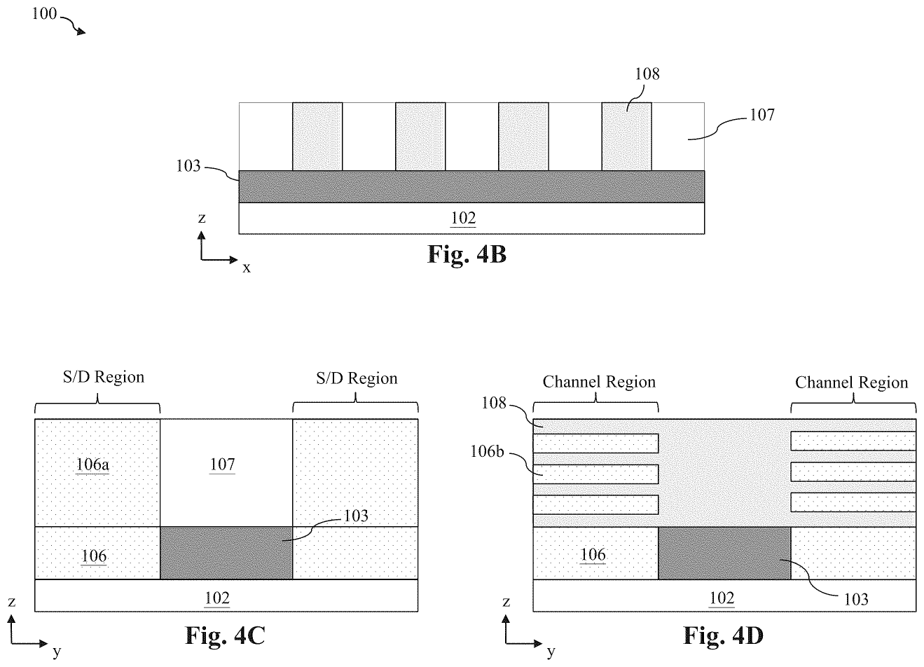

FIG. 1 illustrates a semiconductor structure 100 having a feedthrough via 114 surrounded by a cut-metal-gate (CMG) structure 110. The semiconductor structure 100 includes active regions 106 extending lengthwise along the x direction. The active regions 106 include channel regions (regions under metal gate structures 108) and source/drain (S/D) regions adjacent to the channel regions. The active regions 106 may be fin active regions protruding from a substrate (e.g., substrate 102 in FIGS. 4B-4D). Each of the channel regions may include a stack of semiconductor channels for gate-all-around semiconductor devices. Alternatively, each of the channel regions may include single fin-shaped channels for fin semiconductor devices. The S/D regions adjacent the channel regions include epitaxial S/D features.

Still referring to FIG. 1, the semiconductor structure 100 includes metal gate structures 108 extending lengthwise along the y direction and disposed over the channel regions of the active regions 106. For gate-all-around semiconductor devices, each of the metal gate structures 108 wraps around a stack of semiconductor channels in the channel regions. For fin semiconductor devices, each of the metal gate structures 108 wraps around top and side portions of fin-shaped channels protruding from the substrate.

Still referring to FIG. 1, the semiconductor structure 100 includes cut-metal-gate (CMG) structures 110 cutting through the metal gate structures 108 and extending lengthwise along the x direction. The CMG structures 110 are dielectric features and cuts several metal gate structures 108 into smaller gate portions. The CMG structures 110 can also be referred to as insulating structures 110. Although several CMG structures 110 are shown, the present disclosure is directed to the center CMG structure 110a formed between adjacent active regions 106. Since the CMG structure 110a is formed between adjacent active regions 106, the CMG structure 110a has a width y2 that is smaller than a spacing s1 between adjacent active regions 106. In an embodiment, the spacing s1 is about 100 nm.

Still referring to FIG. 1, the semiconductor structure 100 includes S/D contacts 112 formed over the CMG structure 110a and over epitaxial S/D features of the active regions 106. As shown, the S/D contacts 112 may be slot S/D contacts that extend lengthwise along the y direction. The S/D contacts 112 land on S/D features of the active regions 106. In some embodiments, like the one shown, a single S/D contact 112 may land on multiple S/D features in multiple active regions 106.

Still referring to FIG. 1, the semiconductor structure 100 includes a feedthrough via 114 contacting a bottom surface of the S/D contacts 112 and penetrating through a portion of the CMG structure 110a. The feedthrough via 114 is formed on a backside of the semiconductor structure 100, and it is disposed below the S/D contacts 112 and the unpenetrated portions of the CMG structure 110a. The feedthrough via 114 electrically couples S/D features in the S/D regions to backside metal lines (not shown).

Still referring to FIG. 1, the CMG structure 110a surrounds the feedthrough via 114 and isolates the feedthrough via 114 from the metal gate structures 108. To ensure proper isolation, the width y2 of the CMG structure 110a must be sufficiently greater than the width y1 of the feedthrough via 114. In an embodiment, the CMG structure 110a extends past the feedthrough via 114 by at least 10 nm on either side of the feedthrough via 114. As such, the width y2 is at least 20 nm greater than the width y1. If the CMG structure 110a does not extend far enough (e.g., less than 8 nm on either side of the feedthrough via), there is risk of shorting the metal gate structures 108. On the other hand, the width y2 of the CMG structure 110a must not be too big, which risks cutting into gate portions of the metal gate structures 108 directly over channel regions of the active regions 106. In an embodiment, the CMG structure 110a extends past the feedthrough via 114 by at most 20 nm on either side of the feedthrough via 114. As such, the width y2 is at most 40 nm greater than the width y1. If the CMG structure 110a extends too far (e.g., greater than 45 nm on either side of the feedthrough via), there is risk of cutting through the channel regions of the active regions 106. To allow enough space for the CMG structure 110a in the y direction (which must be big enough to surround the feedthrough via 114), the spacing s1 between adjacent active regions should be greater than twice the width y1 of the feedthrough via 114. In an embodiment, the width y1 is in a range between 20-50 nm, and the spacing s1 is about 100 nm. In some embodiments, a ratio s1/y2 ranges between 2-5, and a ratio y2/y1 ranges between 1.4-3.

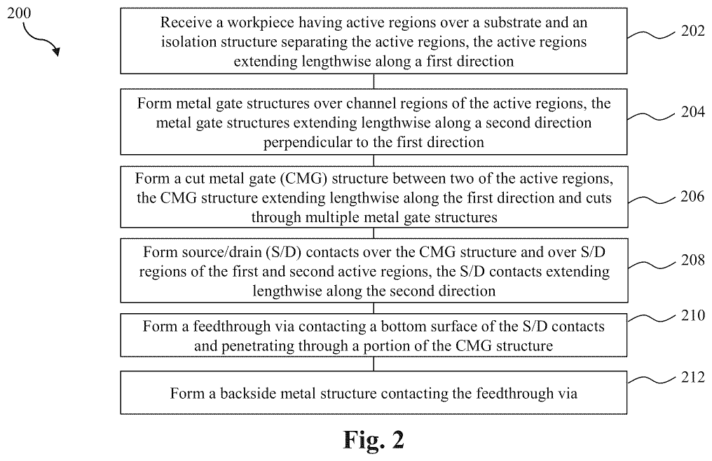

FIG. 2 is a flow chart of a method 200 to form a semiconductor structure 100 having a feedthrough via 114 surrounded by a cut-metal-gate structure 110a. Method 200 is described below with reference to FIGS. 4-12 (including sub-figures A-D), which illustrate the formation of the semiconductor structure 100 at intermediate stages of fabrication and at different top and cross-sectional views, processed in accordance with the method 200. Additional operations can be provided before, during, and after the method 200, and some of the operations described can be moved, replaced, or eliminated for additional embodiments of method 200.

FIG. 4A illustrates a top view of a semiconductor structure 100. FIGS. 4B-4D illustrates cross-sectional views of the semiconductor structure 100 in FIG. 4A, cut along the lines B-B′, C-C′, and D-D′, respectively. Referring to FIG. 4A, the method 200 at operation 202 receives a workpiece having active regions 106 extending lengthwise along the x direction. FIG. 4A shows two active regions 106 spaced apart by an interlayer dielectric (ILD) layer 107. Still referring to FIG. 4A, the method 200 at operation 204 forms metal gate structures 108 over channel regions of the active regions 106. The metal gate structures 108 extend lengthwise along the y direction. The metal gate structures 108 are spaced apart by the ILD layer 107. The ILD layer 107 (and other ILD layers described herein) may include oxide formed with tetraethylorthosilicate, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. In an embodiment, the ILD layer 107 is formed of a low-k dielectric material having a silicon nitride liner (not shown).

Referring now to FIGS. 4B-4D, the active regions 106 are disposed over a substrate 102. The substrate 102 may be a silicon (Si) substrate, or a substrate having other semiconductor materials such as germanium (Ge), silicon carbide (SiC), silicon germanium (SiGe), or diamond. In an embodiment, the active regions 106 are protruding portions of the substrate 102. FIG. 4C shows a cross-sectional view of the source/drain (S/D) regions of the active regions 106, and FIG. 4D shows a cross-sectional view of the channel regions of the active regions 106. In both cases, an isolation structure 103 is disposed over the substrate 102 and isolating adjacent active regions 106 from each other. The isolation structure 103 may be a shallow trench isolation (STI) structure having a dielectric material such as silicon oxide, silicon oxynitride, fluorine-doped silicate glass (FSG), a low-k dielectric, combinations thereof, and/or other suitable materials. In an embodiment, the isolation structure 103 is formed of silicon oxide. In the cross-sectional view of FIG. 4B, multiple metal gate structures 108 land on the isolation structure 103. The ILD layer 107, which separates the metal gate structures 108, is formed over and also landing on the isolation structure 103.

Referring now to FIG. 4C, S/D features 106a are formed over S/D regions of the active regions 106. The S/D features 106a may include n-type epitaxial S/D features that correspond with n-type S/D regions or p-type epitaxial S/D features that correspond with p-type S/D regions. Adjacent S/D features 106a are separated by the ILD layer 107 formed over the isolation structure 103.

Referring now to FIG. 4D, semiconductor channels 106b are formed over channel regions of the active regions 106. The embodiment shown is directed to gate-all-around semiconductor devices having a stack of semiconductor channels 106b over each of the channel regions. Alternatively, for fin-type semiconductor devices, a single fin-shaped channel may be disposed over the channel regions. A metal gate structure 108 is disposed over and wrapping around the semiconductor channels 106b. The metal gate structure 108 is disposed over multiple channel regions.

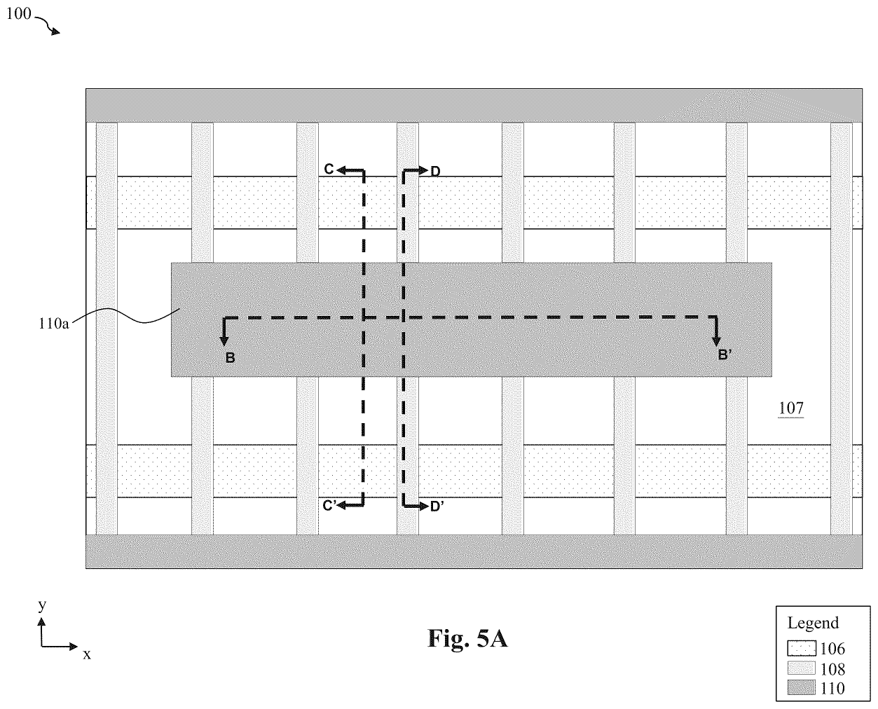

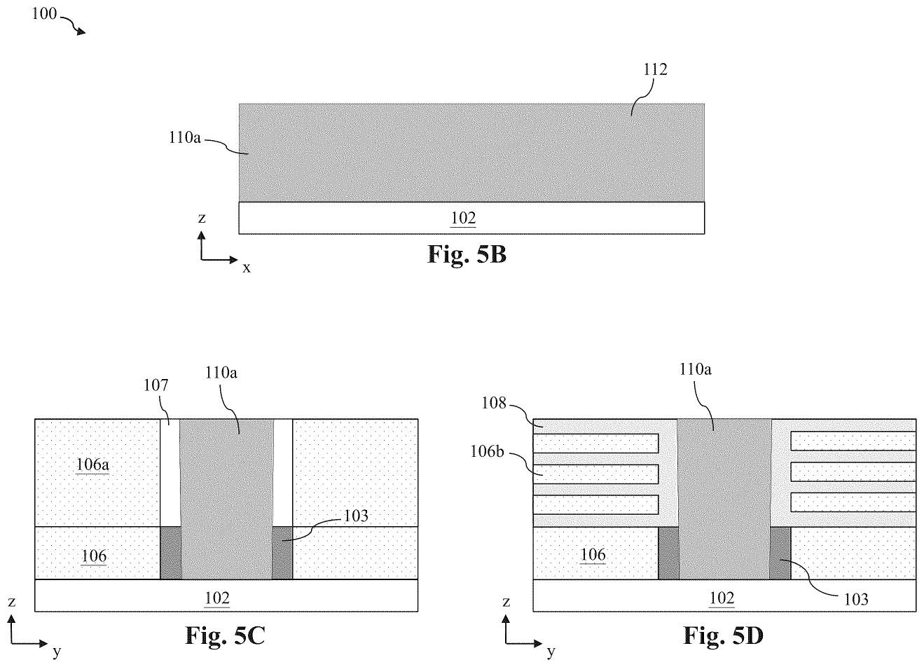

Referring now to FIG. 5A (showing a top view), the method 200 at operation 206 forms a cut-metal-gate (CMG) structure 110a between two of the active regions 106 (i.e., the active regions shown). The CMG structure 110a extends lengthwise along the first direction and cuts through multiple metal gate structures. The CMG structure 110a may be formed by first forming a CMG trench through the metal gate structures 108, the ILD layer 107, and a portion of the isolation structure 103, then the CMG trench is filled with a CMG dielectric material to form the CMG structure 110a. The CMG trench is formed by a suitable patterning and lithography process, and the CMG dielectric material may include silicon oxide, silicon oxynitride, fluorine-doped silicate glass (FSG), a low-k dielectric, combinations thereof, and/or other suitable materials. Note that as shown, additional CMG structures 110 may be formed and they may extend longer in the x direction than the CMG structure 110a. These CMG structures 110 isolate gate regions from other gate regions.

FIGS. 5B-5D illustrates cross-sectional views of the semiconductor structure 100 in FIG. 5A, cut along the lines B-B′. C-C′, and D-D′, respectively. Referring now to FIGS. 5B-5D, the CMG structure 110a cuts through the metal gate structures 108, the ILD layer 107, and the isolation structure 103 to directly contact the substrate 102. In this embodiment, the CMG structure 110a is formed to completely penetrate the isolation structure 103. In another embodiment, the CMG structure 110a is formed to partially penetrate the isolation structure 103. And yet in another embodiment, the CMG structure 110a is formed to further penetrate into a portion of the substrate 102. In all cases, the CMG structure 110a must penetrate the isolation structure 103 at an adequate depth to prepare for the formation of a feedthrough via, as will be explained in more detail below.

Referring to FIG. 5B, the CMG structure 110a spans lengthwise along the x direction over the substrate 102, thereby replacing the isolation structure 103, the ILD layer 107, and the metal gate structures 108 shown in FIG. 4B. Referring to FIG. 5C, the CMG structure 110a penetrates through the ILD layer 107 and the isolation structure 103 to land on the substrate 102. However, portions of the ILD layer 107 and the isolation structure 103 still remain. The remaining portions of the ILD layer 107 isolates the CMG structure 110a from the S/D features 106a along the y direction. The remaining portions of isolation structure 103 isolates the CMG structure 110a from the S/D regions of the active regions 106 along the y direction. Referring to FIG. 5D, the CMG structure 110a penetrates through one of the metal gate structures 108 and penetrates through the isolation structure 103 to land on the substrate 102. The CMG structure 110a separates the metal gate structure 108 into two portions. And a remaining portion of the isolation structure 103 isolates the CMG structure 110a from the channel regions of the active regions 106 along the y direction.

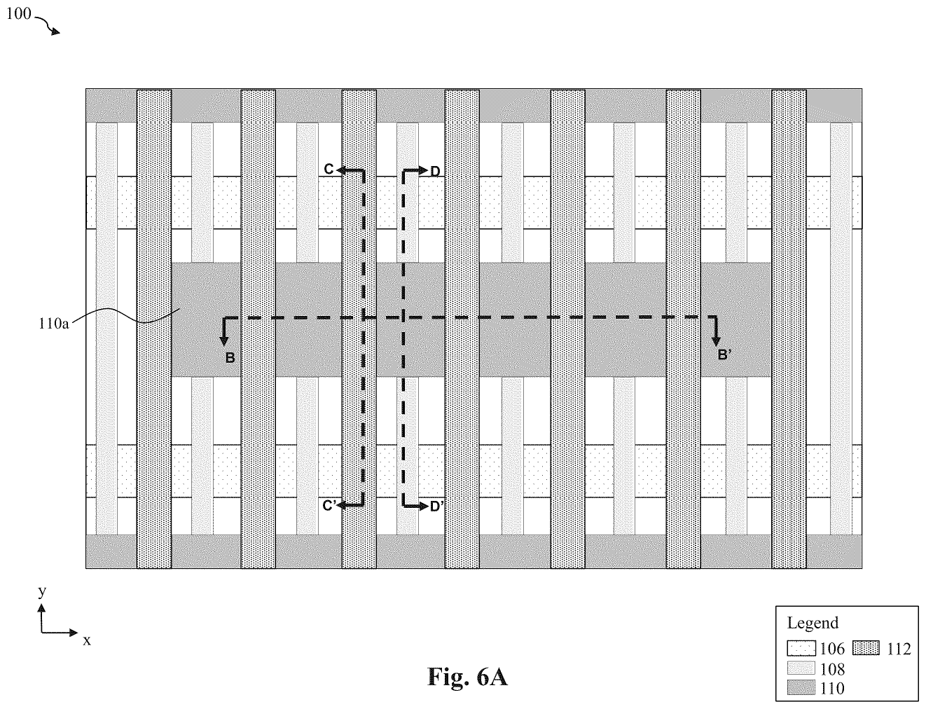

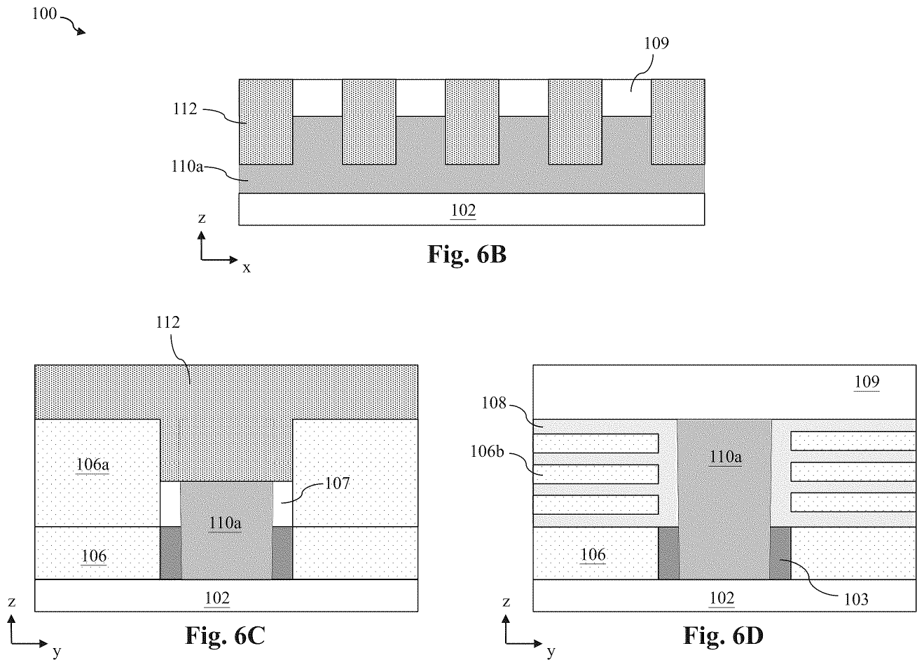

Referring now to FIG. 6A (showing a top view), the method 200 at operation 208 forms source/drain (S/D) contacts 112 over the CMG structure 110a and over S/D regions of the first and second active regions 106. As shown, the S/D contacts 112 may be slot contacts that extend lengthwise along the second direction between metal gate structures 108. The S/D contacts directly contacts the CMG structure 110a and directly contacts the S/D features 106a over the S/D regions of the active regions 106.

FIGS. 6B-6D illustrates cross-sectional views of the semiconductor structure 100 in FIG. 6, cut along the lines B-B′, C-C′, and D-D′, respectively. Referring now to FIGS. 6B-6D. S/D contacts 112 may be formed by first forming an ILD layer 109 over the workpiece (i.e., over the CMG structure 110a, the S/D features 106a, and the metal gate structures 108). Then, S/D trenches are formed through the ILD layer 109 and a portion of the CMG structures 110a. Then, the S/D trenches are filled with a metal material to form the S/D contacts 112. The workpiece may then be planarized by a CMP process. The S/D trenches are formed by a suitable patterning and lithography process, and the metal material for the S/D contacts 112 may include any suitable metals such as tungsten or cobalt. In some embodiments, the S/D contacts 112 may additionally include a barrier layer, such as titanium and titanium nitride.

Referring to FIG. 6B, the S/D contacts 112 partially extends into the CMG structure 110a. As shown, the S/D contacts 112 are isolated from each other along the x direction by the CMG structure 110a and the ILD layer 109. Referring to FIG. 6C, a same S/D contact 112 may land on multiple S/D features 106a. In an embodiment, the S/D contact 112 lands on top and side surfaces of the S/D features 106a. In this case, the S/D contact 112 is formed to penetrate further into the CMG structure 110a and into the ILD layer 107. In this way, there is more surface contact for lower contact resistance between the S/D contacts 112 and the S/D features 106a. Referring to FIG. 6D, the ILD layer 109 remains over the metal gate structure 108 and the CMG structure 110a after the formation of the S/D contacts 112. Referring to FIGS. 6B-6D, after a planarization process, a top surface of the ILD layer 109 is coplanar with a top surface of the S/D contacts 112.

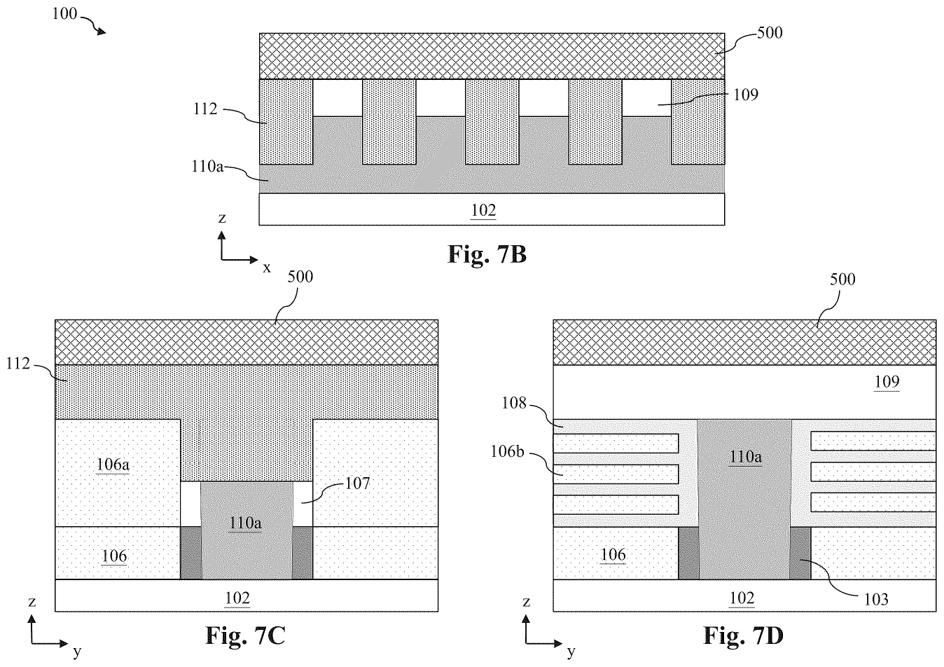

Referring now to FIGS. 7B-7D, the method 200 may perform additional operations to form interconnects (or an interconnect layer 500) over the workpiece. The interconnects 500 include features that electrically couple to the S/D contacts 112, and the metal gate structure 108, such that various devices and/or components can operate as specified by design requirements. The interconnect layer 500 includes a combination of dielectric layers and electrically conductive layers (e.g., metal layers) configured to form various interconnect structures. The conductive layers are configured to form vertical interconnect features, such as device-level contacts and/or vias, and/or horizontal interconnect features, such as conductive lines. Vertical interconnect features typically connect horizontal interconnect features in different layers (or different planes) of the interconnect layer. During operation, the interconnect layer 500 is configured to route signals between the devices and/or the components of the semiconductor structure 100 and/or distribute signals (for example, clock signals, voltage signals, and/or ground signals) to the devices and/or the components of the semiconductor structure 100.

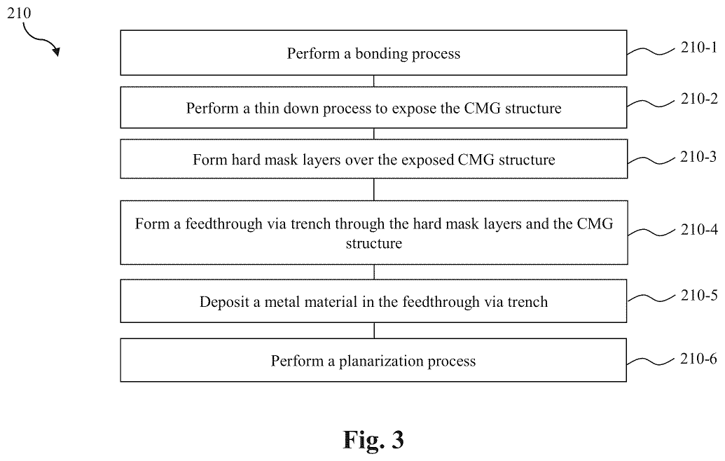

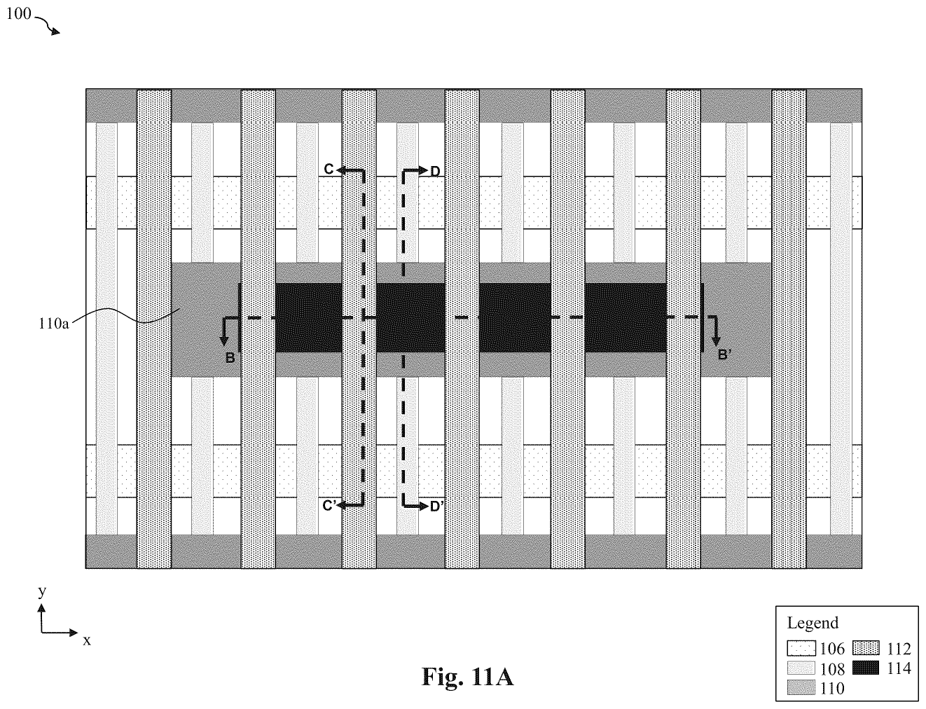

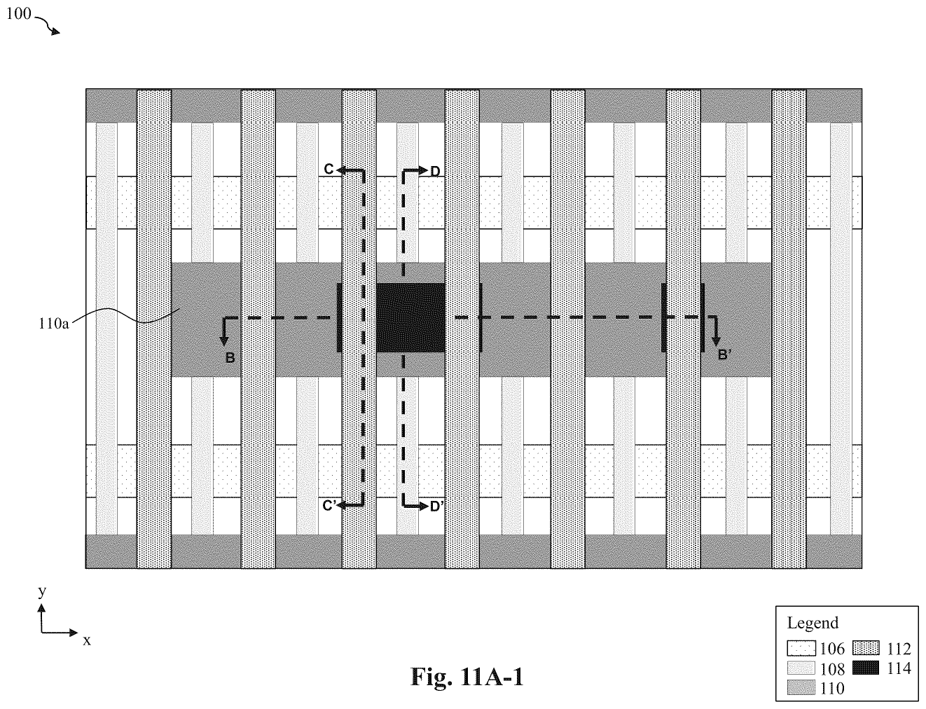

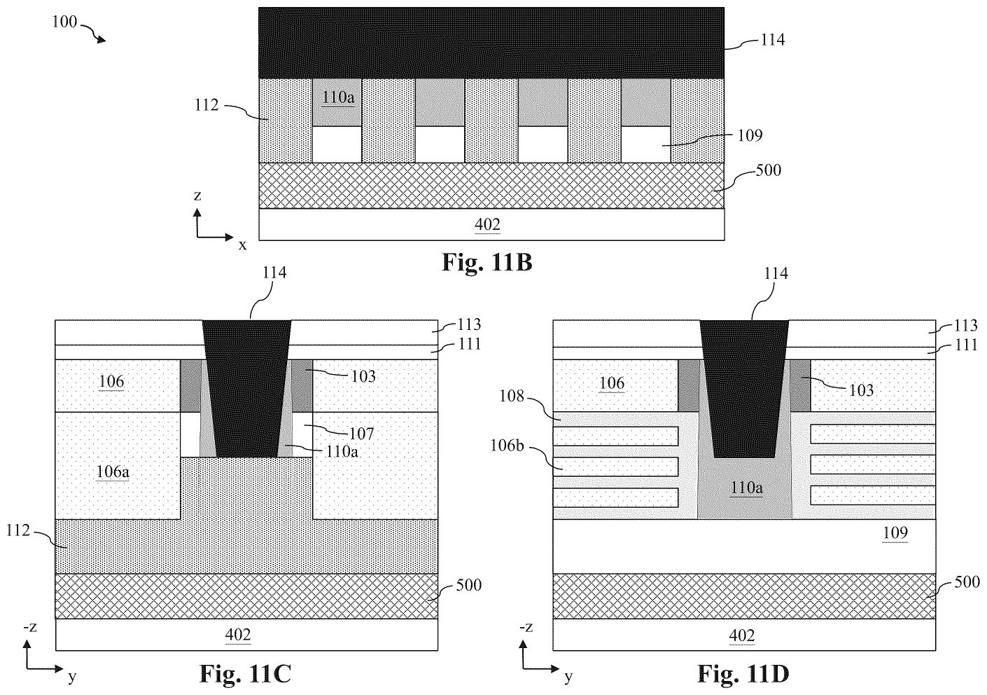

Skipping to FIG. 11A (showing a top view), the method 200 at operation 210 forms a feedthrough via 114 contacting a bottom surface of the S/D contacts 112 and penetrating through a portion of the CMG structure 110a. The feedthrough via 114 is formed within and surrounded by the CMG structure 110a. The CMG structure 110a isolates the feedthrough via 114 from the metal gate structures 108. The feedthrough via 114 extends lengthwise along the x direction to contact one or more S/D contacts 112. Details for forming the feedthrough via 114 is described below with reference to FIG. 3. FIG. 3 illustrates a flow chart of a method to form the feedthrough via 114. This method breaks down operation 210 into further steps 210-1 to 210-6.

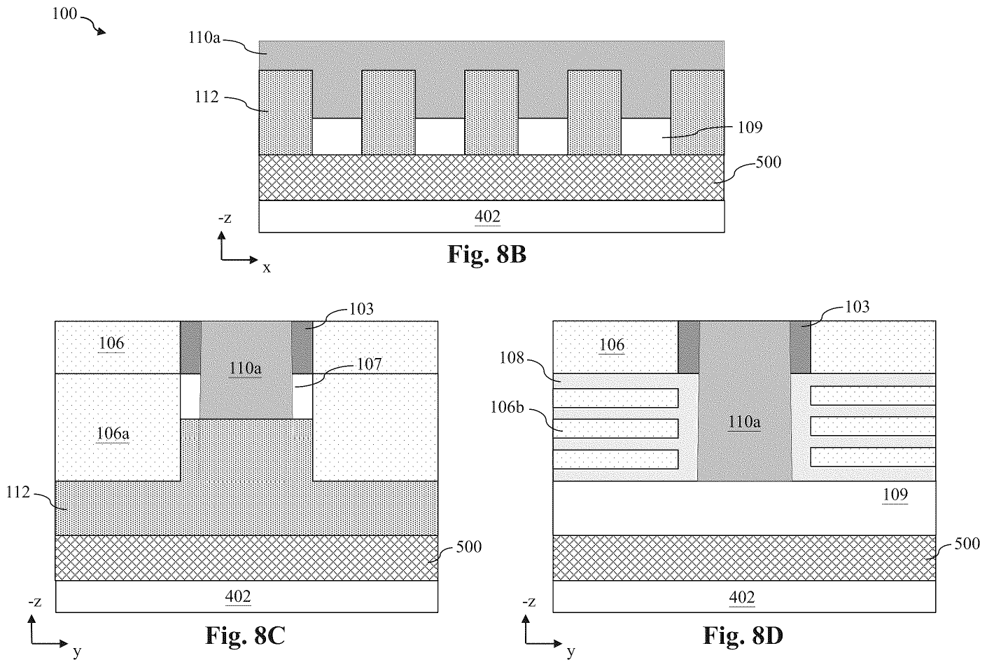

Referring now to FIGS. 8B-8D, the operation 210 at step 210-1 performs a bonding process. The bonding process includes flipping the workpiece of the semiconductor structure 100 and bonding it to a second substrate 402. In this orientation, the −z direction is now facing up. Still referring to FIGS. 8B-8D, the operation 210 at step 210-2 performs a thin down process to expose the CMG structure 110a. The thin down process may be CMP process, a debonding process, or other suitable processes, In the embodiment shown, the thin down process removes the substrate 102 in order to expose the CMG structure 110a.

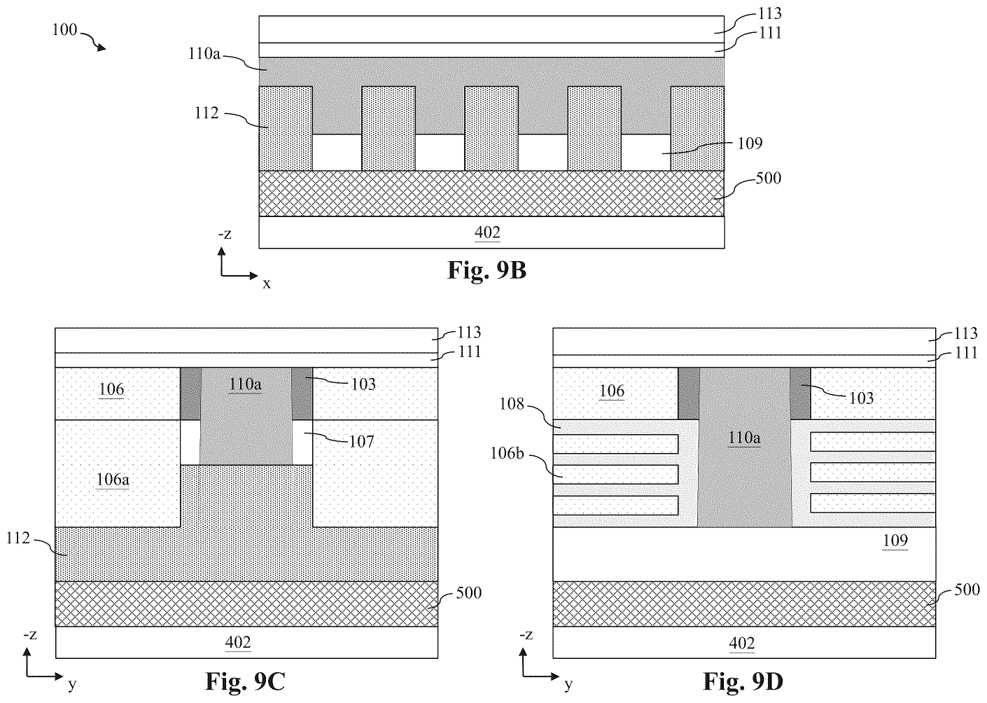

Referring now to FIGS. 9B-9D, the operation 210 at step 210-3 forms hard mask layers over the exposed CMG structure 110a. As shown, the hard mask layers may include a silicon nitride layer 111 and a silicon oxide layer 113 according to some embodiments. These layers are formed by any suitable deposition techniques, such as CVD, PVD, ALD, HDPCVD, RPCVD, PECVD, LPCVD, ALCVD, APCVD, plating, other suitable methods, or combinations thereof.

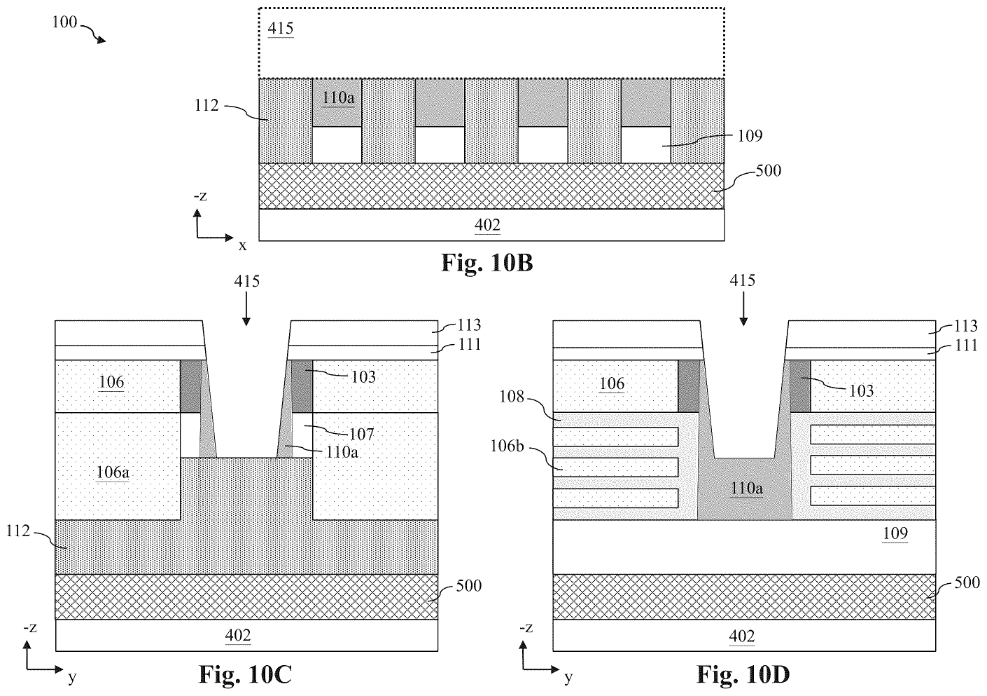

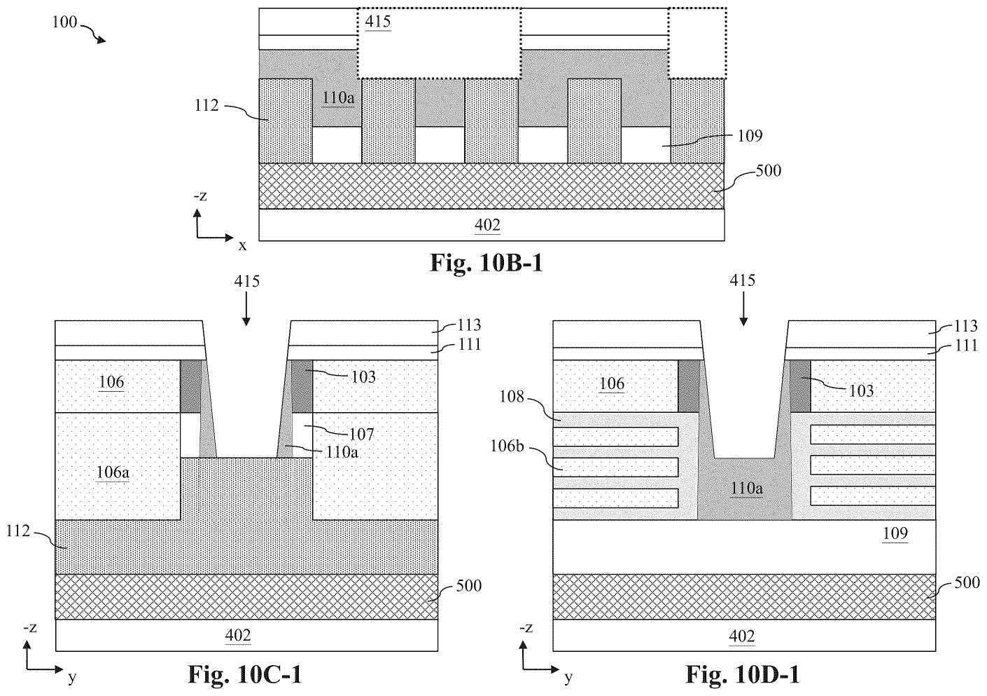

Referring now to FIGS. 10B-10D, the operation 210 at step 210-4 forms a feedthrough via trench 415 through the hard mask layers and the CMG structure 110a. The feedthrough via trench 415 may be formed by first performing a lithography process and an etch process to pattern the hard mask layers (i.e., layers 111 and 113) to form an opening, then using the patterned hard mask layers as an etch mask for etching through the CMG structure 110a. As shown in FIG. 10B, the feedthrough via trench 415 (shown by the dashed box) exposes top surfaces of the S/D contacts 112 and a top surface of the CMG structure 110a. In this view, the top surfaces of the S/D contacts 112 may be coplanar with a top horizontal surface of the CMG structure 110a. As shown in FIG. 10C, the feedthrough via trench 415 exposes side surfaces of the hard mask layers (i.e., layers 111 and 113), side surfaces of the CMG structure 110a, and a horizontal surface of an S/D contact 112. In this view, the feedthrough via trench 415 completely penetrates through the CMG structure 110a to expose the S/D contacts 112. As shown in FIG. 10D, the feedthrough via trench 415 exposes side surfaces of the hard mask layers (i.e., layers 111 and 113), side surfaces of the CMG structure 110a, and a horizontal surface of the CMG structure 110a. In this view, the feedthrough via trench 415 only partially penetrates through the CMG structure 110a. The feedthrough via trench 415 is formed to not expose any portions of the metal gate structures 108.

Referring now to FIGS. 10B-1 to 10D-1, another embodiment of forming the feedthrough via trench 415 is shown. Turning specifically to FIG. 10B-1, the CMG structure 110a may be patterned (through selective patterning of the hard mask layers 111 and 113) and etched such that some S/D contacts 112 are exposed while other S/D contacts 112 remain covered. As shown, the CMG structure 110a may then isolate the covered S/D contacts from the exposed S/D contacts. In this embodiment, multiple feedthrough via trenches 415 may be formed.

Referring now to FIG. 11A (showing a top view), the operation 210 at step 210-5 deposits a metal material into the feedthrough via trench 415 as shown in FIGS. 10B-10D, thereby forming a feedthrough via 114. FIG. 11A resembles FIG. 1 and FIG. 11A will not be described again for the sake of brevity. Referring now to FIG. 11A-1, in another embodiment, multiple feedthrough vias 114 are formed. This follows the embodiment shown in 10B-1 to 10D-1. In this case, the multiple feedthrough vias 114 are isolated by the CMG structure 110a.

FIGS. 11B-11D illustrates cross-sectional views of the semiconductor structure 100 in FIG. 11A, cut along the lines B-B′, C-C′, and D-D′, respectively. Referring to FIGS. 11B-11D, the operation 210 at step 210-6 performs a planarization process (e.g., CMP) to planarize the feedthrough via 114 such that a top surface of the feedthrough via 114 is coplanar with a top surface of the hard mask layers (i.e., layers 111 and 113). In another embodiment, the hard mask layers 111 and 113 are removed, and the planarization process may planarize the feedthrough via 114 such that a top surface of the feedthrough via 114 is coplanar with a top surface of the active regions 106.

Referring to FIG. 11B, the feedthrough via 114 lands on and directly contacts top surfaces of the S/D contacts 112 and a top surface of the CMG structure 110a. In the embodiment shown, the feedthrough via 114 simultaneously lands on and couples to multiple S/D contacts 112. In other embodiments, when feedthrough via trenches 415 are formed to only expose some S/D contacts 112 while keeping the other S/D contacts 112 covered (See FIG. 10B-1), the feedthrough vias 114 may land on some S/D contacts 112 while being isolated from other S/D contacts 112 by the CMG structure 110a. Referring to FIG. 11C, the feedthrough via 114 penetrates through and directly contacts side surfaces of the hard mask layers (i.e., layers 111 and 113), side surfaces of the CMG structure 110a, and a horizontal surface of an S/D contact 112. In this view, there remains portions of the CMG structure 110a directly between the feedthrough via 114 and the ILD layer 107, and between the feedthrough via 114 and the isolation structure 103. Referring to FIG. 11D, the feedthrough via 114 penetrates through and directly contacts side surfaces of the hard mask layers (i.e., layers 111 and 113), side surfaces of the CMG structure 110a, and a horizontal surface of the CMG structure 110a. In this view, there remains portions of the CMG structure 110a directly between the feedthrough via 114 and the isolation structure 103. Still referring to FIG. 11D, the feedthrough via 114 is embedded within and surrounded by the CMG structure 110a such that the feedthrough via 114 is isolated from the metal gate structures 108. To that effect, the CMG structure 110a should be wider in the y direction than the portion of the feedthrough via 114 penetrating through the CMG structure 110a.

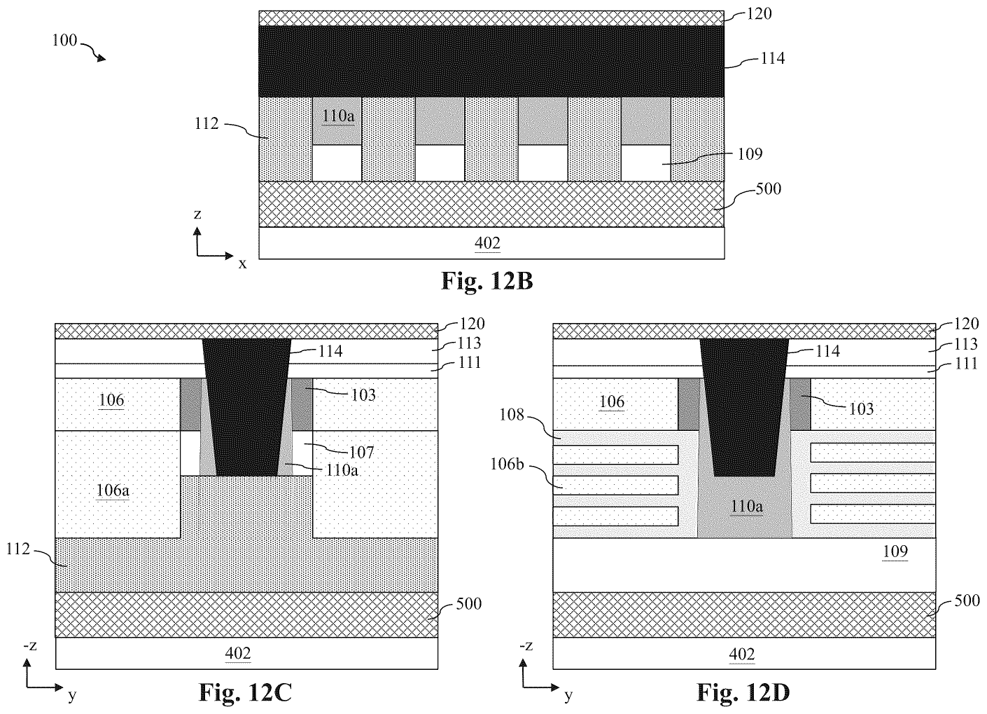

Referring now to FIGS. 12B-12D, the method 200 at operation 212 forms a backside metal structure 120 contacting the feedthrough via 114. The backside metal structure 120 may include a backside power rail or other metal lines and interconnects for coupling to the S/D contacts 112 from a backside of the workpiece. The method 200 may perform further steps to complete fabrication of the semiconductor structure 100. Additional operations can be provided before, during, and after method 200, and some of the operations described can be moved, replaced, or eliminated for additional embodiments of method 200.

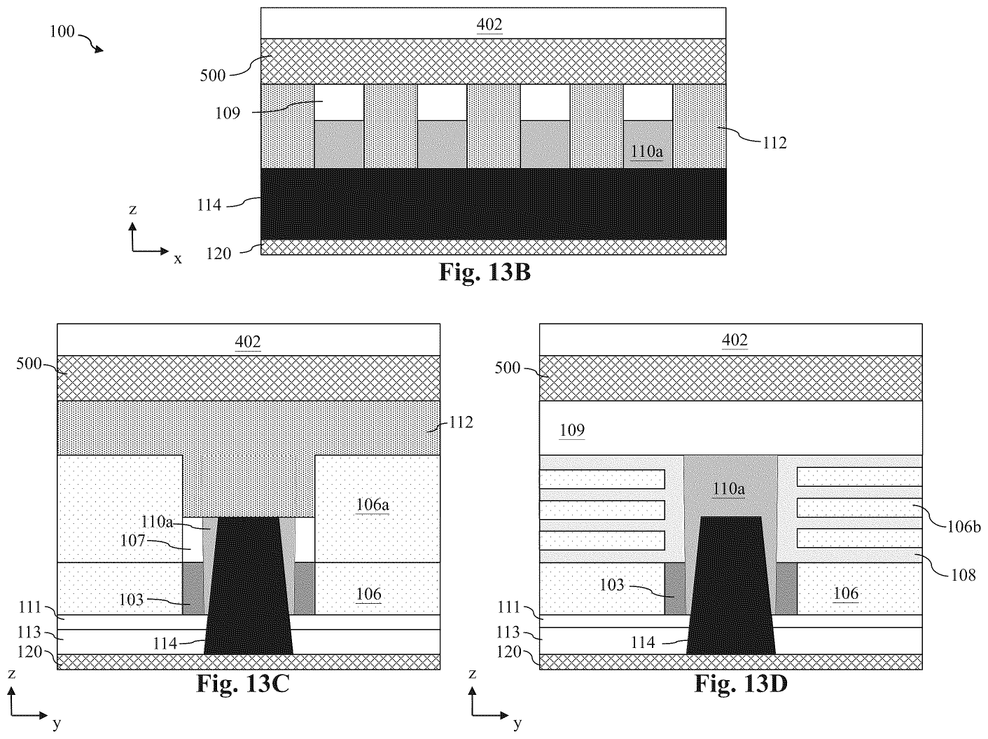

FIGS. 13B-13D illustrate the same semiconductor structure 100 shown in FIGS. 12B-12D, but the semiconductor structure 100 is flipped back to the positive z direction for purposes of explanation. In this orientation, the feedthrough via 114 is formed under a bottom surface of the S/D contacts 112 and under a portion of the CMG structure 110a (i.e., portion not penetrated through). The feedthrough via 114 is formed surrounded by inner surfaces of the CMG structure 110a along the y direction. The CMG structure 110a directly contacts the S/D contacts 112, the ILD layer 107, the isolation structure 103, the metal gate structures 108, and the ILD layer 109. In this embodiment, where the CMG structure 110a completely penetrates through the isolation structure 103, the CMG structure 110a may also isolate the feedthrough via 114 from contacting the isolation structure 103.

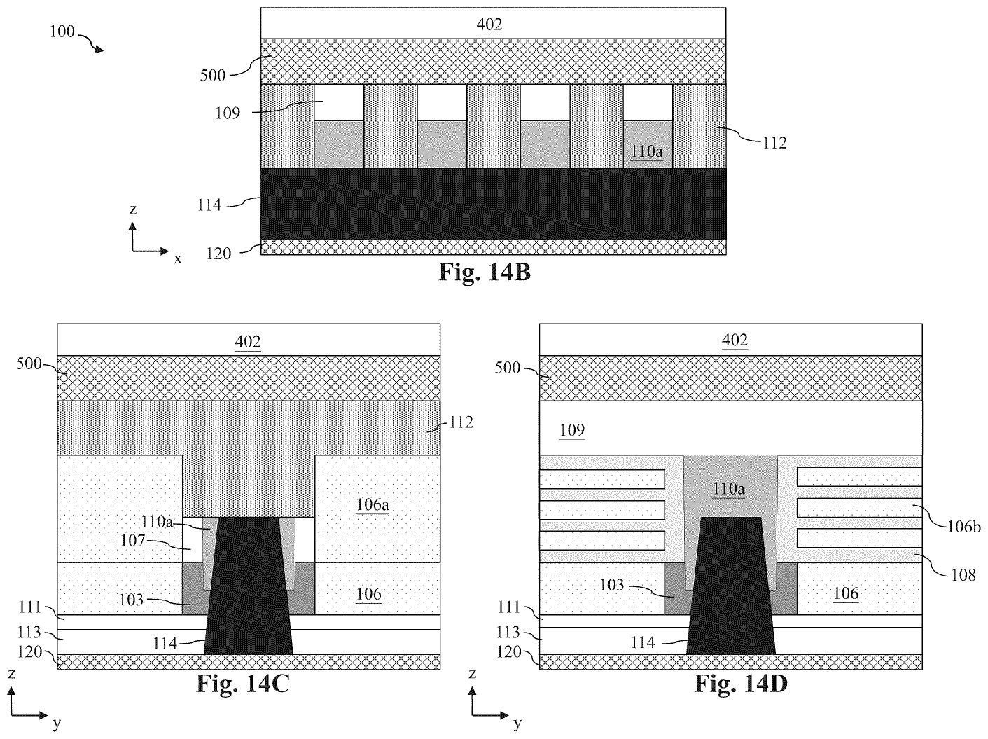

FIGS. 14B-14D illustrate another embodiment of the semiconductor structure 100 having a feedthrough via 114 surrounded by a CMG structure 110a. FIGS. 14B-14D resembles FIGS. 13B-13D, except that the CMG structure 110a only partially penetrates the isolation structure 103. As mentioned previously, as long as the CMG structure 110a penetrate the isolation structure 103 at an adequate depth (i.e., a depth to cut through the metal gate structures 108 and to isolate the feedthrough via 114), the CMG structure 110a need not completely penetrate through the isolation structure 103. In an embodiment, the depth of penetration should be at least half the height of the isolation structure 103. For cases where the CMG structure 110a only partially penetrates the isolation structure 103, the feedthrough via 114 may additionally be in direct contact with inner surfaces of the isolation structure 103.

The isolation structure 103, the ILD layers 107 and 109, and the CMG structure 110a has been described to include a variety of dielectric materials. In an embodiment, the isolation structure 103, the ILD layers 107 and 109, and the CMG structure 110a have different dielectric materials for etching selectivity. For example, the isolation structure 103 includes silicon oxide, the ILD layers 107 and 109 includes a low-k dielectric material lined with an etch stop silicon nitride layer, and the CMG structure 110a includes silicon oxynitride. The different materials allow for etch selectivity during the etching processes to form the different trenches described herein (e.g., CMG trenches, S/D trenches, and feedthrough via trenches). If there is overlay shift, the different compositions and the etching selectivity will constrain the etching to be within the CMG structure 110a.

Although not limiting, the present disclosure offers advantages for semiconductor structures having feedthrough vias. One example advantage is that the feedthrough via is formed directly between adjacent active regions instead of in a separate feedthrough cell region, thereby saving space. Another example advantage is that the feedthrough via is formed within and surrounded by a cut-metal-gate structure, where the cut-metal-gate structure isolates the feedthrough via from the metal gates. Another example advantage is that the feedthrough via directly contacts the source/drain contacts, providing a direct signal route from a backside of the semiconductor structure to the source/drain features. Another example advantage is that the cut-metal-gate structure may also isolate adjacent source/drain contacts for selective coupling of the feedthrough via to the source/drain contacts.

One aspect of the present disclosure pertains to a semiconductor structure. The semiconductor structure includes first and second active regions extending lengthwise along a first direction and metal gate structures over channels of the first and second active regions. The metal gate structures extend lengthwise along a second direction perpendicular to the first direction. The semiconductor structure includes an insulating structure cutting through the metal gate structures and extending lengthwise along the first direction. The insulating structure is disposed between the first and the second active regions along the second direction. The semiconductor structure includes source/drain (S/D) contacts over the insulating structure and over S/D features of the first and second active regions. The S/D contacts extend lengthwise along the second direction. And the semiconductor structure includes a feedthrough via contacting a bottom surface of the S/D contacts and penetrating through a portion of the insulating structure. The insulating structure surrounds the feedthrough via and isolates the feedthrough via from the metal gate structures.

In an embodiment, an isolation structure separates the first and second active regions along the second direction, and an interlayer dielectric (ILD) layer is disposed over the isolation structure. The insulating structure cuts through the isolation structure and the ILD layer. In a further embodiment, along the second direction, the insulating structure is in direct contact with and directly between the feedthrough via and the ILD layer, and along the second direction, the insulating structure is in direct contact with and directly between the feedthrough via and the isolation structure.

In an embodiment, each of the S/D contacts land on top and side surfaces of the S/D features. In an embodiment, along the second direction, the insulating structure extends past the feedthrough via by at least 10 nm on either side of the feedthrough via. In an embodiment, along the second direction, the insulating structure extends past the feedthrough via by at most 20 nm on either side of the feedthrough via.

In an embodiment, the insulating structure has a first width along the second direction, the feedthrough via has a second width along the second direction, and the first width is greater than the second width. In a further embodiment, the first width is greater than the second width by at least 20 nm. In another further embodiment, a spacing between the first and second active regions is greater than twice the second width. In a further embodiment, the spacing between the first and second active regions is about 100 nm. In a further embodiment, the second width is in a range of 20-50 nm.

Another aspect of the present disclosure pertains to a semiconductor structure. The structure includes a first active region having first semiconductor channels and first source/drain (S/D) features adjacent the first semiconductor channels. The structure includes a second active region having second semiconductor channels and second S/D features adjacent the second semiconductor channels. The structure includes an isolation structure between the first active region and the second active region. The structure includes a metal gate structure over the first and second semiconductor channels. The structure includes an insulating structure cutting through the metal gate structure and the isolation structure. And the structure includes a feedthrough via under the insulating structure. The feedthrough via has a penetrating portion that penetrates through a portion of the insulating structure, and the insulating structure isolates the penetrating portion of the feedthrough via from the metal gate structure.

In an embodiment, the structure further includes an S/D contact over and in direct contact with the first and second S/D features. In a further embodiment, the feedthrough via is under the S/D contact and in direct contact with the S/D contact. In another further embodiment, the S/D contact is disposed along top and side surfaces of the first and second S/D features. In another further embodiment, the first active region includes third S/D features, and the second active region includes fourth S/D features, and the structure further includes a second S/D contact over and in direct contact with the third and fourth S/D features, wherein the feedthrough via is also under the second S/D contact and in direct contact with the second S/D contact.

Another aspect of the present disclosure pertains to a method of forming a semiconductor structure. The method includes receiving a workpiece having active regions over a substrate and an isolation structure separating the active regions, the active regions extending lengthwise along a first direction. The method includes forming metal gate structures over channel regions of the active regions, the metal gate structures extending lengthwise along a second direction perpendicular to the first direction. The method includes forming an insulating structure between two of the active regions, the insulating structure extending lengthwise along the first direction and cuts through multiple metal gate structures, separating first portions of the metal gate structures from second portions of the metal gate structures. The method includes forming source/drain (S/D) contacts over the insulating structure and over S/D regions of the first and second active regions, the S/D contacts extending lengthwise along the second direction. The method includes forming a feedthrough via contacting a bottom surface of the S/D contacts and penetrating through a portion of the insulating structure. The insulating structure surrounds the feedthrough via and isolates the feedthrough via from the metal gate structures.

In an embodiment, the S/D contacts are slot S/D contacts separated from each other by the insulating structure, and each of the S/D contacts land on multiple S/D features in the S/D regions.

In an embodiment, the forming of the feedthrough via further includes: performing an etching process to the insulating structure to form a feedthrough via trench in the insulating structure such that the S/D contacts are exposed within the feedthrough via trench; depositing a conductive material in the feedthrough via trench; and performing a planarize process to form the feedthrough via.

In an embodiment, after forming the feedthrough via, a portion of the insulating structure remains between the feedthrough via and the isolation structure along the second direction.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor structure, comprising:
first and second active regions extending lengthwise along a first direction;
metal gate structures over channels of the first and second active regions, the metal gate structures extending lengthwise along a second direction perpendicular to the first direction;
an insulating structure cutting through the metal gate structures and extending lengthwise along the first direction, wherein the insulating structure is disposed between the first and the second active regions along the second direction;
source/drain (S/D) contacts over the insulating structure and over S/D features of the first and second active regions, the S/D contacts extending lengthwise along the second direction; and
a feedthrough via contacting a bottom surface of the S/D contacts and penetrating through a portion of the insulating structure,
wherein the insulating structure surrounds the feedthrough via and isolates the feedthrough via from the metal gate structures.

2. The semiconductor structure of claim 1, further comprising:
an isolation structure separating the first and second active regions along the second direction; and
an interlayer dielectric (ILD) layer over the isolation structure,
wherein the insulating structure cuts through the isolation structure and the ILD layer.

3. The semiconductor structure of claim 2,
wherein along the second direction, the insulating structure is in direct contact with and directly between the feedthrough via and the ILD layer, and
wherein along the second direction, the insulating structure is in direct contact with and directly between the feedthrough via and the isolation structure.

4. The semiconductor structure of claim 1, wherein each of the S/D contacts land on top and side surfaces of the S/D features.

5. The semiconductor structure of claim 1, wherein along the second direction, the insulating structure extends past the feedthrough via by at least 10 nm on either side of the feedthrough via.

6. The semiconductor structure of claim 1, wherein along the second direction, the insulating structure extends past the feedthrough via by at most 20 nm on either side of the feedthrough via.

7. The semiconductor structure of claim 1, wherein the insulating structure has a first width along the second direction, the feedthrough via has a second width along the second direction, and the first width is greater than the second width.

8. The semiconductor structure of claim 7, wherein the first width is greater than the second width by at least 20 nm.

9. The semiconductor structure of claim 7, wherein a spacing between the first and second active regions is greater than twice the second width.

10. The semiconductor structure of claim 9, wherein the spacing between the first and second active regions is about 100 nm.

11. The semiconductor structure of claim 10, wherein the second width is in a range of 20-50 nm.

12. A semiconductor structure, comprising:
a first active region having first semiconductor channels and first source/drain (S/D) features adjacent the first semiconductor channels;
a second active region having second semiconductor channels and second S/D features adjacent the second semiconductor channels;
an isolation structure between the first active region and the second active region;
a metal gate structure over the first and second semiconductor channels;
an insulating structure cutting through the metal gate structure and the isolation structure; and
a feedthrough via under the insulating structure, the feedthrough via having a penetrating portion that penetrates through a portion of the insulating structure, and the insulating structure isolates the penetrating portion of the feedthrough via from the metal gate structure.

13. The semiconductor structure of claim 12, further comprising:
an S/D contact over and in direct contact with the first and second S/D features.

14. The semiconductor structure of claim 13, wherein the feedthrough via is under the S/D contact and in direct contact with the S/D contact.

15. The semiconductor structure of claim 13, wherein the S/D contact is disposed along top and side surfaces of the first and second S/D features.

16. The semiconductor structure of claim 13, wherein the first active region includes third S/D features and the second active region includes fourth S/D features, further comprising:
a second S/D contact over and in direct contact with the third and fourth S/D features, wherein the feedthrough via is also under the second S/D contact and in direct contact with the second S/D contact.

17. A method of forming a semiconductor structure, comprising:
receiving a workpiece having active regions over a substrate and an isolation structure separating the active regions, the active regions extending lengthwise along a first direction;
forming metal gate structures over channel regions of the active regions, the metal gate structures extending lengthwise along a second direction perpendicular to the first direction;
forming an insulating structure between two of the active regions, the insulating structure extending lengthwise along the first direction and cuts through multiple metal gate structures, separating first portions of the metal gate structures from second portions of the metal gate structures;
forming source/drain (S/D) contacts over the insulating structure and over S/D regions of the first and second active regions, the S/D contacts extending lengthwise along the second direction; and
forming a feedthrough via contacting a bottom surface of the S/D contacts and penetrating through a portion of the insulating structure,
wherein the insulating structure surrounds the feedthrough via and isolates the feedthrough via from the metal gate structures.

18. The method of claim 17, wherein
the S/D contacts are slot S/D contacts separated from each other by the insulating structure; and
each of the S/D contacts land on multiple S/D features in the S/D regions.

19. The method of claim 17, wherein the forming of the feedthrough via further includes:
performing an etching process to the insulating structure to form a feedthrough via trench in the insulating structure such that the S/D contacts are exposed within the feedthrough via trench;
depositing a conductive material in the feedthrough via trench; and
performing a planarize process to form the feedthrough via.

20. The method of claim 17, wherein after forming the feedthrough via, a portion of the insulating structure remains between the feedthrough via and the isolation structure along the second direction.
